(19) United States
(12) Patent Application Publication
(10) Pub. No.: US 2025/0081713 A1
(43) Pub. Date: Mar. 6, 2025

(54) IMAGING DEVICE AND METHOD FOR MANUFACTURING THE SAME

(71) Applicant: Panasonic Intellectual Property Management Co., Ltd., Osaka (JP)

(72) Inventors: SHUNSUKE ISONO, Osaka (JP); YUUKO TOMEKAWA, Osaka (JP); JUNJI HIRASE, Osaka (JP); RYOTA SAKAIDA, Toyama (JP)

(21) Appl. No.: 18/950,278

(22) Filed: Nov. 18, 2024

Related U.S. Application Data
(63) Continuation of application No. PCT/JP2023/015262, filed on Apr. 17, 2023.

(30) Foreign Application Priority Data
May 23, 2022 (JP) 2022-084139

(51) Int. Cl. H10K 39/32

(52) U.S. Cl. CPC H10K 39/32

(57) ABSTRACT

A method for manufacturing an imaging device includes forming a photoelectric conversion film such that a ratio of an overlapping area of the photoelectric conversion film and a support substrate in plan view to an area of the support substrate in plan view is greater than 0% and less than 100%. The method includes performing first etching to reduce an area of the photoelectric conversion film in plan view.

### BACKGROUND

### 1. Technical Field

The present disclosure relates to an imaging device and a method for manufacturing the imaging device.

### 2. Description of the Related Art

Japanese Unexamined Patent Application Publication No. 2006-32714 describes an example of an imaging device. According to Japanese Unexamined Patent Application Publication No. 2006-32714, a photoelectric conversion film is formed by an application method, and then dry etching is performed.

### SUMMARY

One non-limiting and exemplary embodiment provides a highly reliable imaging device.

In one general aspect, the techniques disclosed here feature a method for manufacturing an imaging device. The method includes forming a photoelectric conversion film such that a ratio of an overlapping area of the photoelectric conversion film and a support substrate in plan view to an area of the support substrate in plan view is greater than 0% and less than 100%. The method includes performing first etching to reduce an area of the photoelectric conversion film in plan view.

The technology according to the present disclosure is suitable for providing a highly reliable imaging device.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a plan view of an imaging device according to a first embodiment;

FIG. 2 is a sectional view of the imaging device according to the first embodiment;

FIG. 3 is a sectional view of the imaging device according to the first embodiment;

FIG. 4A is an enlarged sectional view of the imaging device according to the first embodiment;

FIG. 4B is an enlarged sectional view of the imaging device according to the first embodiment;

FIG. 4C is an enlarged sectional view of the imaging device according to the first embodiment;

FIG. 4D is an enlarged sectional view of a support substrate according to the first embodiment;

FIG. 4E is an enlarged plan view of the imaging device according to the first embodiment;

FIG. 5 illustrates an imaging mechanism;

FIG. 6A illustrates a step of a manufacturing method according to the first embodiment;

FIG. 6B illustrates a step of the manufacturing method according to the first embodiment;

FIG. 6C illustrates a step of the manufacturing method according to the first embodiment;

FIG. 6D illustrates a step of the manufacturing method according to the first embodiment;

FIG. 6E illustrates a step of the manufacturing method according to the first embodiment;

FIG. 6F illustrates a step of the manufacturing method according to the first embodiment;

FIG. 6G illustrates a step of the manufacturing method according to the first embodiment;

FIG. 6H illustrates a step of the manufacturing method according to the first embodiment;

FIG. 6I illustrates a step of the manufacturing method according to the first embodiment;

FIG. 6J illustrates a step of the manufacturing method according to the first embodiment;

FIG. 6K illustrates a step of the manufacturing method according to the first embodiment;

FIG. 6L illustrates a step of the manufacturing method according to the first embodiment;

FIG. 6M illustrates a step of the manufacturing method according to the first embodiment;

FIG. 6N illustrates a step of the manufacturing method according to the first embodiment;

FIG. 6O illustrates a step of the manufacturing method according to the first embodiment;

FIG. 7 is a flowchart of the manufacturing method according to the first embodiment;

FIG. 8 is a schematic diagram of a camera system according to a second embodiment;

FIG. 9A illustrates a step of a manufacturing method according to a third embodiment;

FIG. 9B illustrates a step of the manufacturing method according to the third embodiment;

FIG. 9C illustrates a step of the manufacturing method according to the third embodiment;

FIG. 9D illustrates a step of the manufacturing method according to the third embodiment;

FIG. 9E illustrates a step of the manufacturing method according to the third embodiment;

FIG. 9F illustrates a step of the manufacturing method according to the third embodiment;

FIG. 9G illustrates a step of the manufacturing method according to the third embodiment;

FIG. 9H illustrates a step of the manufacturing method according to the third embodiment; and

FIG. 10 is a flowchart of the manufacturing method according to the third embodiment.

### DETAILED DESCRIPTIONS

### Underlying Knowledge Forming Basis of the Present Disclosure

In manufacturing an imaging device, assume that a photoelectric conversion film is formed over an entire region that overlaps a support substrate in plan view and then subjected to etching. In this case, a large portion of the photoelectric conversion film is removed by etching, and a large amount of etching residue may be generated. This may reduce the reliability of the manufactured imaging device. The photoelectric conversion film and the support substrate are bonded by a weak force, such as van der Waals force, and therefore the film formation stress applied to the substrate is preferably reduced. The present inventors have studied technologies suitable for providing a highly reliable imaging device.

### Summary of Aspects of the Present Disclosure

A method for manufacturing an imaging device according to a first aspect of the present disclosure includes:
forming a photoelectric conversion film such that a ratio of an overlapping area of the photoelectric conversion film and a support substrate in plan view to an area of the support substrate in plan view is greater than 0% and less than 100%; and
performing first etching to reduce an area of the photoelectric conversion film in plan view.

According to the first aspect, an amount of reduction in the area of the photoelectric conversion film due to the first etching can be reduced, and the generation of etching residue can be suppressed. In addition, a film formation stress applied to the substrate can be reduced. Therefore, the technology according to the first aspect is suitable for providing a highly reliable imaging device.

According to a second aspect of the present disclosure, for example, in the method according to the first aspect,
a shadow mask may be used to form the photoelectric conversion film.

According to the second aspect, the above-described overlapping area can be easily controlled.

According to a third aspect of the present disclosure, for example, in the method according to the first aspect or the second aspect,
a ratio of the area reduced by the first etching to the area of the support substrate in plan view may be greater than 0% and less than or equal to 20%.

According to the third aspect, the generation of etching residue can be suppressed.

According to a fourth aspect of the present disclosure, for example, in the method according to any one of the first to third aspects,
the support substrate may include a semiconductor substrate, a diffusing region provided on the semiconductor substrate, and a pixel electrode electrically connected to the diffusing region, and
the first etching may be performed such that a portion of the photoelectric conversion film that overlaps the pixel electrode in plan view remains.

According to the fourth aspect, an imaging device in which the pixel electrode and the photoelectric conversion film overlap in plan view can be manufactured.

According to a fifth aspect of the present disclosure, for example, in the method according to the fourth aspect,
the support substrate may further include a connection electrode that is electrically separated from the pixel electrode, and
the first etching may be performed such that a portion of the photoelectric conversion film that overlaps the connection electrode in plan view is removed.

According to the fifth aspect, an imaging device in which the connection electrode and the photoelectric conversion film do not overlap in plan view can be manufactured.

According to a sixth aspect of the present disclosure, for example, in the method according to any one of the first to fifth aspects,
an insulating film mask may be used in the first etching.

The insulating film mask is not easily etched. Therefore, according to the sixth aspect, the generation of etching residue can be suppressed.

According to a seventh aspect of the present disclosure, for example, in the method according to any one of the first to sixth aspects,
the photoelectric conversion film may be formed above the support substrate so that the photoelectric conversion film does not overlap a predetermined region of the support substrate in plan view, and
the method may further include:
forming a specific insulating film such that the specific insulating film includes a first insulator and a second insulator, that the first insulator is positioned above the predetermined region, that the first insulator overlaps the predetermined region in plan view, that the second insulator is positioned above the photoelectric conversion film, and that the second insulator overlaps the photoelectric conversion film in plan view; and
performing second etching to remove a portion of the specific insulating film that is positioned between the first insulator and the second insulator, thereby forming a first insulating film corresponding to the first insulator and a second insulating film corresponding to the second insulator.

According to the seventh aspect, in a region that overlaps the predetermined region in plan view, the first insulating film that does not overlap the photoelectric conversion film in plan view can be formed without a process of removing the photoelectric conversion film. In addition, the second insulating film that overlaps the photoelectric conversion film in plan view can be formed. The first insulating film and the second insulating film can be formed at the same time by forming the specific insulating film and performing the second etching.

According to an eighth aspect of the present disclosure, for example, in the method according to any one of the first to seventh aspects,
the photoelectric conversion film is formed above the support substrate, and
the method may further include:
forming a counter electrode such that a ratio of an overlapping area of the counter electrode and the support substrate in plan view to the area of the support substrate in plan view is greater than 0% and less than 100%, that the counter electrode is positioned above the photoelectric conversion film, and that the counter electrode overlaps the photoelectric conversion film in plan view; and
performing third etching to reduce an area of the counter electrode in plan view.

According to the eighth aspect, an amount of reduction in the area of the counter electrode due to the third etching can be reduced, and the generation of etching residue can be suppressed.

According to a ninth aspect of the present disclosure, for example, the method according to any one of the first to eighth aspects may further include:
performing third etching after a structure is formed in which the photoelectric conversion film is positioned above the support substrate, in which a counter electrode is positioned above the photoelectric conversion film, in which the counter electrode overlaps the photoelectric conversion film in plan view, in which the first insulating film is positioned above the support substrate, in which the first insulating film is separate from the photoelectric conversion film and from the counter electrode in plan view, in which the second insulating film is positioned above the counter electrode, and in which the second insulating film overlaps the counter electrode in plan view, and
the third etching may include
   etching in which the second insulating film serves as a mask and in which the area of the counter electrode in plan view is reduced, and
   etching in which the first insulating film and the photoelectric conversion film serve as a mask and in which a first recess is formed in the support substrate.

According to the ninth aspect, the area of the counter electrode in plan view can be reduced, and the first recess can be formed.

According to a tenth aspect of the present disclosure, for example, in the method according to any one of the first to ninth aspects,
the support substrate may include a connection electrode,
the method may further include performing third etching after a structure is formed in which the photoelectric conversion film is positioned above the connection electrode, in which the photoelectric conversion film overlaps the connection electrode in plan view, in which the counter electrode is positioned above the photoelectric conversion film, and in which the counter electrode overlaps the photoelectric conversion film in plan view, the third etching having a higher selectivity with respect to the counter electrode than with respect to the photoelectric conversion film, thereby removing a portion of the counter electrode that overlaps the connection electrode in plan view, and
the first etching may be performed after the third etching to remove a portion of the photoelectric conversion film that overlaps the connection electrode in plan view.

According to the tenth aspect, the connection electrode can be protected from the third etching by the photoelectric conversion film.

According to an eleventh aspect of the present disclosure, for example, in the method according to any one of the first to tenth aspects,
the photoelectric conversion film may be formed above the support substrate such that the photoelectric conversion film does not overlap a predetermined region of the support substrate in plan view, and
the method may further include:
forming a specific film body such that the specific film body includes a first film portion and a second film portion, that the first film portion is positioned above the predetermined region, that the first film portion overlaps the predetermined region in plan view, that the second film portion is positioned above the photoelectric conversion film, and that the second film portion overlaps the photoelectric conversion film in plan view; and
performing fourth etching to remove an intermediate portion of the specific film body that is positioned between the first film portion and the second film portion, thereby forming a first film body corresponding to the first film portion and a second film body corresponding to the second film portion.

According to the eleventh aspect, in a region that overlaps the predetermined region in plan view, the first film body that does not overlap the photoelectric conversion film in plan view can be formed without a process of removing the photoelectric conversion film. In addition, the second film body that overlaps the photoelectric conversion film in plan view can be formed. The first film body and the second film body can be formed at the same time by forming the specific film body and performing the fourth etching.

According to a twelfth aspect of the present disclosure, for example, in the method according to the eleventh aspect, the fourth etching may be performed to form a second recess in a portion of the support substrate that overlaps the intermediate portion in plan view.

According to the twelfth aspect, the second recess may be formed when the first film body and the second film body are formed.

An imaging device according to a thirteenth aspect of the present disclosure includes:
a support substrate having a first recess;
a first insulating film positioned above the support substrate; and
a photoelectric conversion film positioned above the support substrate, and
a first continuous surface is provided at a position separate from the photoelectric conversion film in plan view, the first continuous surface including a first defining surface that defines the first recess and a side surface of the first insulating film.

The first recess may prevent a movement of moisture along an upper surface of the support substrate. Therefore, the technology according to the thirteenth aspect is suitable for providing a highly reliable imaging device.

According to a fourteenth aspect of the present disclosure, for example, the imaging device according to the thirteenth aspect may further include:
at least one film, and
the at least one film may include a portion positioned in the first recess.

According to the fourteenth aspect, the film includes the portion positioned in the first recess. This may increase the adhesion strength between the support substrate and the film. When the adhesion is increased, the entrance of moisture from the outside can be suppressed, and a highly reliable imaging device may be provided.

According to a fifteenth aspect of the present disclosure, for example, in the imaging device according to the fourteenth aspect, the at least one film may include at least one selected from the group consisting of a light-shielding film and a second insulating film.

According to a sixteenth aspect of the present disclosure, for example, the imaging device according to any one of the thirteenth to fifteenth aspects may further include:
a first film;
the first recess may include a second recess;
the first film may include an inner portion positioned in the first recess; and
a second continuous surface may be provided, the second continuous surface including a second defining surface that defines the second recess and a side surface of the inner portion.

According to a seventeenth aspect of the present disclosure, for example, the imaging device according to the sixteenth aspect may further include:
a second film; and
wherein the second film may be in contact with the second continuous surface.

According to an eighteenth aspect of the present disclosure, for example, in the imaging device according to any one of the thirteenth to seventeenth aspects,
the support substrate may include an array of pixel electrodes, and
in plan view, a length of the first recess in a direction along the first continuous surface is longer than a length of the array in the direction along the first continuous surface.

The structure according to the fifteenth to eighteenth aspects is an example of a structure of the imaging device.

According to a nineteenth aspect of the present disclosure, for example, in the imaging device according to any one of the thirteenth to eighteenth aspects,
the first recess may define a step on the support substrate.

The step may prevent a movement of moisture along an upper surface of the support substrate. Therefore, the technology according to the nineteenth aspect is suitable for providing a highly reliable imaging device.

In this specification, numerical values, shapes, materials, components, the arrangement of and connections between the components, steps, the order of the steps, etc., described in embodiments are examples and are not intended to limit the present disclosure. Various aspects described in this specification may be combined with one another as long as there is no contradiction. In the drawings, some elements may be omitted. In the drawings, dimensions, for example, may be exaggerated. In the following description, components having substantially the same functions are denoted by the same reference signs, and redundant description may be omitted or simplified.

According to an aspect of the present disclosure, an imaging device includes an upper layer and a lower layer. The upper layer includes a photoelectric conversion film that performs photoelectric conversion of converting incident light into electric signals. The lower layer includes a signal-processing circuit including a silicon-based CMOS circuit for transmitting the electric signals obtained by the photoelectric conversion film to the outside. Thus, the photoelectric conversion film and the signal-processing circuit are stacked, and are therefore independently designable.

In this specification, the terms including “up”, “down”, “out”, “row”, and “column” are used to designate the relative arrangement between members, and are not intended to limit the position of the imaging device in use or limit the positions of members of the imaging device being manufactured or the position of a manufacturing device. This also applies to an X direction, a Y direction, and a Z direction. In the drawings, the X direction and the Y direction may correspond to sideways directions. The Z direction may correspond to an up-down direction.

In this specification, the term “main component” means the component that is the most abundant on a mass basis. For example, the main component may be a component whose content is greater than 50 mass %. In a specific example, the main component may be a component whose content is greater than 80 mass %.

In this specification, the term “plan view” refers to a view in a thickness direction of the support substrate.

In this specification, the expression “element A includes element B” means that element A includes at least a portion of element B. The expression “element A and element B overlap in plan view” means that at least a portion of element A and at least a portion of element B overlap in plan view.

In this specification, ordinal numbers, such as first, second, third, and so on may be used. When an element is designated using an ordinal number, the existence of an element with a lower ordinal number is not essential. The ordinal numbers may be changed as necessary. The ordinal numbers are not intended to limit the interpretation of the elements for which the ordinal numbers are used. This also applies to the terms “specific” and “predetermined”.

### First Embodiment

### 1. Example of Overall Structure of Imaging Device 1

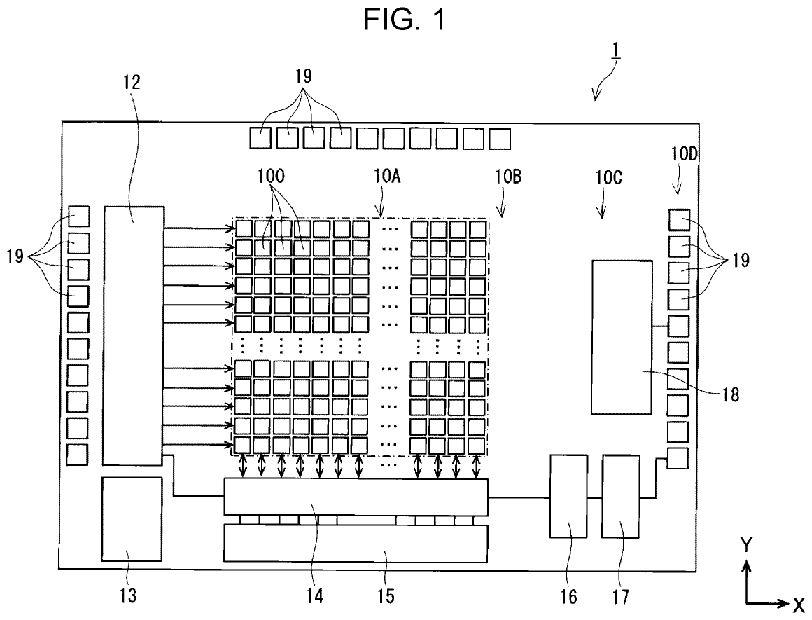

FIG. 1 is a plan view of an imaging device 1 according to a first embodiment. The imaging device 1 includes pixels 100 arranged in the X and Y directions in a matrix pattern. Each pixel 100 includes a reading circuit. The imaging device 1 includes a pixel region 10A including the pixels 100.

The imaging device 1 includes the pixel region 10A, a counter electrode region 10B, a peripheral circuit region 10C, and a pad region 10D arranged in that order. In the counter electrode region 10B, a voltage is applied to a counter electrode. A peripheral circuit is provided in the peripheral circuit region 10C. The peripheral circuit includes a perpendicular driver 12, a timing generator 13, a signal-processing circuit 14, a horizontal driver 15, a low-voltage differential signaling (LVDS) device 16, a serial converter 17, and a counter-electrode voltage supplier 18. The pad region 10D includes pads 19.

The perpendicular driver 12 performs a control operation of reading signals from each reading circuit. The timing generator 13 generates and supplies timing for driving the imaging device 1. The timing generator 13 also performs reading control, such as sample reading and partial reading.

Each column circuit of the signal-processing circuit 14 subjects signals output from a corresponding column of reading circuits to correlated double sampling (CDS) process and analog-to-digital (AD) conversion in that order. The obtained digital signals are stored in a memory provided for each column circuit.

The horizontal driver 15 performs a control operation of successively reading signals associated with the pixels 100 in one row stored in the memory of the signal-processing circuit 14 and outputting the read signals to the LVDS device 16. The LVDS device 16 transmits digital signals. The serial converter 17 converts the parallel digital signals input thereto to serial signals and outputs the converted signals.

In a first modification, the signal-processing circuit 14 performs the correlated double sampling process but does not perform the analog-to-digital conversion. An AD conversion circuit is provided in place of the LVDS device 16, and the serial converter 17 is omitted.

In a second modification, the signal-processing circuit 14 performs the correlated double sampling process but does not perform the analog-to-digital conversion. The LVDS device 16 and the serial converter 17 are omitted, and an AD conversion circuit is provided outside a chip on which the imaging device 1 is provided.

In a third modification, the signal-processing circuit 14, the LVDS device 16, and the serial converter 17 are disposed in each of the regions adjacent to and on both sides of the pixel region 10A. The columns of reading circuits in the pixel region 10A are processed by the two signal-processing circuits 14. For example, one-half of the columns of reading circuits (for example, odd-numbered columns) are processed by the signal-processing circuit 14 in a region adjacent to and on one side of the pixel region 10A. The remaining half of the columns of reading circuits (for example, even-numbered columns) are processed by the signal-processing circuit 14 in a region adjacent to and on the other side of the pixel region 10A.

### 2. Example of Detailed Structure of Imaging Device 1

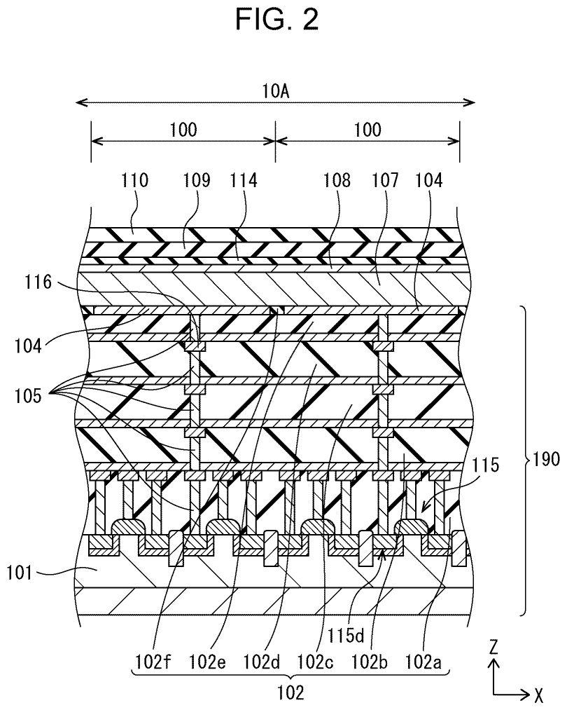

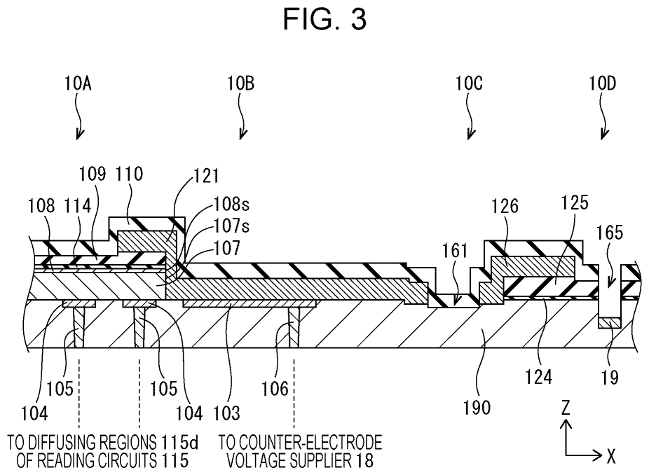

FIGS. 2 and 3 are sectional views of the imaging device 1 according to the first embodiment. The imaging device 1 includes a support substrate 190. The support substrate 190 includes a semiconductor substrate 101, reading circuits 115, an insulating structure 102, pixel plugs 105, a connection plug 106, pixel electrodes 104, a connection electrode 103, and the pads 19.

As illustrated in FIG. 2, the insulating structure 102 is provided above the semiconductor substrate 101. The insulating structure 102 includes insulating layers 102a to 102f. The semiconductor substrate 101 includes, for example, silicon (Si). The insulating structure 102 and the insulating layers 102a to 102f include, for example, silicon oxide (SiO₂).

In pixel region 10A, each pixel 100 includes the corresponding reading circuit 115. The reading circuits 115 are provided on the semiconductor substrate 101. Each reading circuit 115 includes a diffusing region 115d provided on the semiconductor substrate 101. The diffusing region 115d serves as a charge storage.

In the pixel region 10A, the pixel electrodes 104 are provided on an upper surface of the insulating structure 102 and arranged in the X and Y directions in a matrix pattern with constant intervals therebetween. The insulating layer 102f is interposed between the pixel electrodes 104 that are adjacent to each other. The arrangement of the pixel electrodes 104 corresponds to the arrangement of the pixels 100 illustrated in FIG. 1. The pixel electrodes 104 have a uniform film thickness and flat upper surfaces.

Each pixel electrode 104 is electrically connected to the corresponding reading circuit 115 by the pixel plugs 105. Specifically, the pixel plugs 105 extend through the insulating layers 102a to 102e and electrically connect the pixel electrode 104 to the reading circuit 115 together with multilayer wiring. In FIG. 2, reference sign 116 denotes a wire in the uppermost layer of the multilayer wiring.

In this example, each reading circuit 115 includes a metal-oxide-semiconductor field-effect transistor (MOSFET) or a thin-film transistor (TFT). The reading circuit 115 is shielded from light by a light-shielding layer (not illustrated) provided in, for example, the insulating structure 102.

The pixel electrodes 104 may include at least one selected from the group consisting of a metal and a metal compound. The metal may be, for example, titanium (Ti), tantalum (Ta), aluminum (Al), tungsten (W), or copper (Cu). The metal compound may be, for example, a metal nitride. The metal nitride may be, for example, titanium nitride (TiN) or tantalum nitride (TaN). The pixel electrodes 104 may include polysilicon doped with impurities to impart conductivity. In the present embodiment, the pixel electrodes 104 have a multilayer structure including a layer including titanium and a layer including titanium nitride. The layer including titanium is in contact with a photoelectric conversion film 107, and the layer including titanium nitride is in contact with the pixel plugs 105.

The pixel plugs 105 may include a metal. The metal may be, for example, copper (Cu) or tungsten (W). In the present embodiment, the pixel plugs 105 include copper.

The photoelectric conversion film 107 is provided above the pixel electrodes 104 and the insulating layer 102f. A counter electrode 108, an insulating film 114, an insulating film 109, and an insulating film 110 are stacked above the photoelectric conversion film 107 in that order in the upward direction. Although not illustrated, in the pixel region 10A, a color filter is provided above the insulating film 110. In addition, microlenses are provided above the color filter.

The photoelectric conversion film 107 includes a photoelectric conversion layer that generates hole-electron pairs. The photoelectric conversion film 107 may include an electron transport layer that transports electrons, and may also include a hole transport layer that transports holes. The photoelectric conversion film 107 may include an electron blocking layer that blocks electrons, and may also include a hole blocking layer that blocks holes.

The photoelectric conversion film 107 includes, for example, an organic material. In the present embodiment, the photoelectric conversion film 107 includes an organic material as the main component. The organic material may be an organic semiconductor material. The photoelectric conversion film 107 may include one or more organic semiconductor layers. Commonly known organic p-type semiconductor materials and organic n-type semiconductor materials may be used as the organic semiconductor material. The photoelectric conversion film 107 may be a mixed film of organic donor molecules and acceptor molecules, a mixed film of semiconductor carbon nanotubes and acceptor molecules, or a film containing quantum dots. The photoelectric conversion film 107 may include an inorganic material, such as amorphous silicon. The photoelectric conversion film 107 may be a metal oxide film. The metal oxide film is, for example, a copper oxide (CuO) film.

The counter electrode 108 faces the pixel electrodes 104. The counter electrode 108 includes a light-transmitting conductive material. The conductive material included in the counter electrode 108 is, for example, indium tin oxide (ITO) or indium zinc oxide (IZO). In the present embodiment, the counter electrode 108 includes ITO as the main component.

The insulating film 114 includes, for example, aluminum oxide (AlO). The insulating film 109 and the insulating film 110 include, for example, silicon oxynitride (SiON). In the present embodiment, the insulating film 114 includes aluminum oxide as the main component. The insulating film 109 and the insulating film 110 include silicon oxynitride as the main component.

As illustrated in FIG. 3, the counter electrode region 10B is provided outside the pixel region 10A. The connection electrode 103 is provided in the counter electrode region 10B. The connection electrode 103 is electrically connected to the counter-electrode voltage supplier 18 by the connection plug 106.

The connection electrode 103 may include at least one selected from the group consisting of a metal and a metal compound. The metal may be, for example, titanium (Ti), tantalum (Ta), aluminum (Al), tungsten (W), or copper (Cu). The metal compound may be, for example, a metal nitride. The metal nitride may be, for example, titanium nitride (TiN) or tantalum nitride (TaN). The connection electrode 103 may include polysilicon doped with impurities to impart conductivity. In the present embodiment, the connection electrode 103 has a multilayer structure including a layer including titanium and a layer including titanium nitride. The layer including titanium is in contact with a light-shielding film 121, and the layer including titanium nitride is in contact with the connection plug 106.

The connection plug 106 may include a metal. The metal may be, for example, copper (Cu) or tungsten (W). In the present embodiment, the connection plug 106 includes copper.

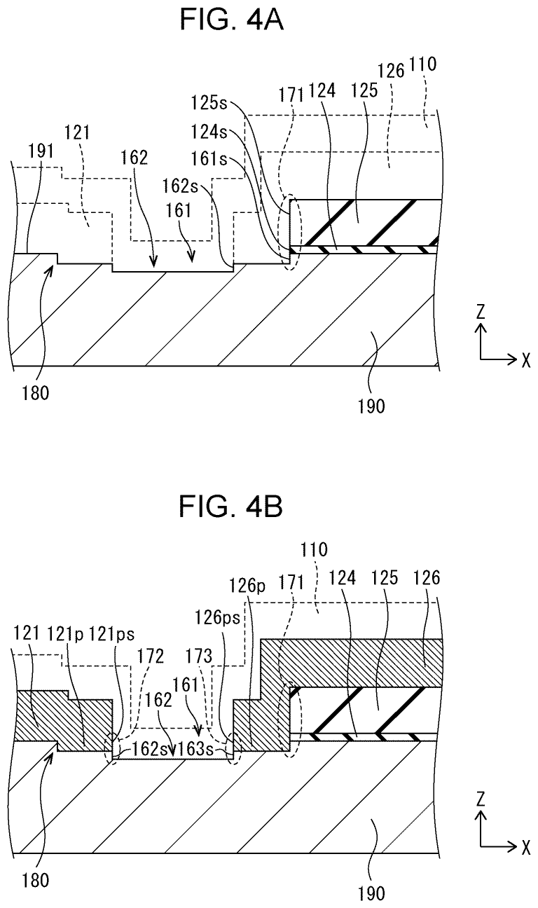

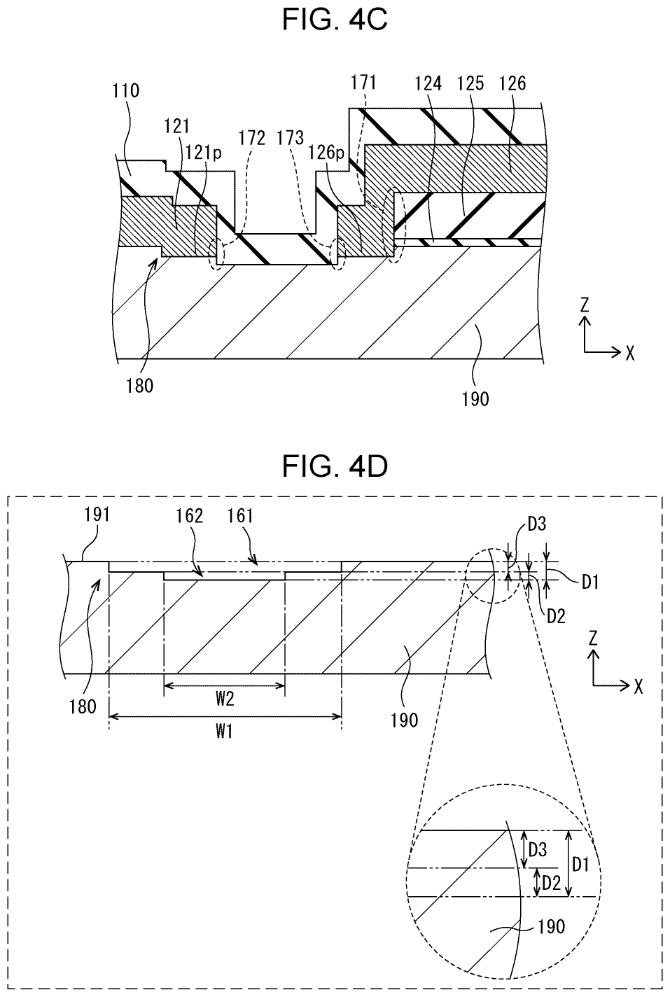

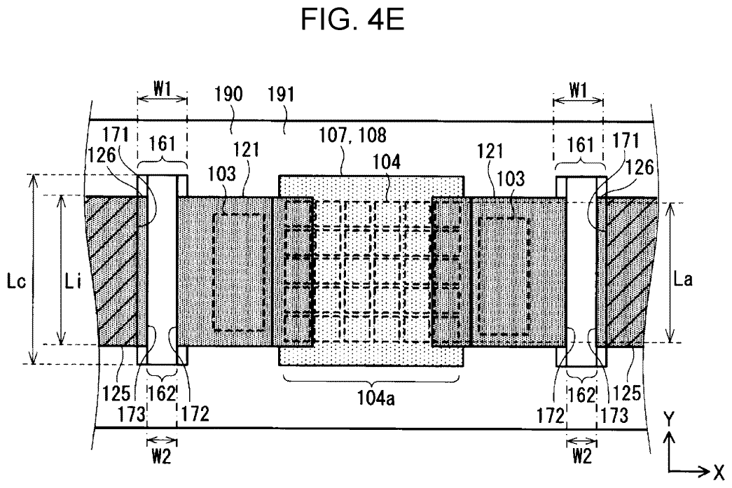

The light-shielding film 121 is provided on the insulating film 110 in a region around an effective pixel region in plan view. In the present embodiment, the light-shielding film 121 overlaps at least one of the pixel electrodes 104 in plan view. The pixels 100 including the pixel electrodes 104 that overlap the light-shielding film 121 may be used as optical black (OB) pixels. In FIG. 4E described below, the pixels 100 including the pixel electrodes 104 in the leftmost and rightmost columns may correspond to the OB pixels. Specifically, the pixels 100 in the effective pixel region do not overlap the light-shielding film 121 in plan view. The OB pixels positioned around the effective pixel region overlap the light-shielding film 121 in plan view and are therefore shielded from light by the light-shielding film 121. The signals generated by the pixels 100 in the effective pixel region are corrected by the signals generated by the OB pixels, so that signals with reduced noise can be generated. The light-shielding film 121 electrically connects the counter electrode 108 to the connection electrode 103. In the present embodiment, the light-shielding film 121 overlaps the counter electrode 108 and the connection electrode 103 in plan view.

The light-shielding film 121 may, for example, include at least one selected from the group consisting of a metal and a metal compound. In a specific example, the light-shielding film 121 includes at least one selected from the group consisting of titanium (Ti), titanium nitride (TiN), aluminum (Al), silicon (Si), copper-doped aluminum (AlCu), copper (Cu), tungsten (W), gold (Au), silver (Ag), nickel (Ni), and cobalt (Co). The light-shielding film 121 may include an alloy including at least two of the materials mentioned above. The light-shielding film 121 may have a single layer structure or a multilayer structure. In the present embodiment, the light-shielding film 121 has a multilayer structure including a layer including titanium and a layer including a titanium compound. Specifically, the layer including titanium is a lower layer and the layer including the titanium compound is an upper layer.

In the present embodiment, the numbers of connection electrodes 103, connection plugs 106, counter-electrode voltage suppliers 18, and other components connected to one counter electrode 108 are not particularly limited. The numbers may be increased or reduced as appropriate in consideration of, for example, the chip area and wire widths.

As illustrated in FIG. 3, the peripheral circuit region 10C is provided outside the counter electrode region 10B. A peripheral circuit is provided in the peripheral circuit region 10C. The peripheral circuit region 10C includes a metal layer including, for example, copper (Cu).

In the peripheral circuit region 10C, an insulating film 124, an insulating film 125, and a light-shielding film 126 are provided in that order in the upward direction. The material of the insulating film 124 may be a material usable as the material of the insulating film 114. The material of the insulating film 125 may be a material usable as the material of the insulating film 109. The material of the light-shielding film 126 may be a material usable as the material of the light-shielding film 121. The insulating film 114, the insulating film 109, the insulating film 124, and the insulating film 125 may be referred to as protective films.

The insulating film 110 extends not only in the pixel region 10A but also in the counter electrode region 10B and the peripheral circuit region 10C. The insulating film 110 covers the insulating film 109, the light-shielding film 121, the insulating film 125, and the light-shielding film 126 from above.

As illustrated in FIG. 3, the pad region 10D is provided outside the peripheral circuit region 10C. The pad region 10D includes a recess 165. The pads 19 are provided on a bottom surface of the recess 165. Although not illustrated in detail, the pads 19 are electrically connected to circuits including a signal input/output circuit and a voltage supply circuit.

The structure of the imaging device 1 will be further described with reference to FIGS. 4A to 4E as well as FIGS. 1 to 3. FIGS. 4A to 4C are enlarged sectional views of the imaging device 1 according to the first embodiment. FIG. 4D is an enlarged sectional view of the support substrate 190 according to the first embodiment. FIG. 4E is an enlarged plan view of the imaging device 1 according to the first embodiment. In FIG. 4A, the light-shielding film 121, the light-shielding film 126, and the insulating film 110 are shown by the dotted lines. In FIG. 4B, the insulating film 110 is shown by the dotted lines. In FIG. 4E, the insulating film 110 is not illustrated. In the example illustrated in FIGS. 3 and 4E, a side surface 107s of the photoelectric conversion film 107 and a side surface 108s of the counter electrode 108 are continuous in plan view.

As is clear from the above description referring to FIGS. 1 to 3, the imaging device 1 includes the support substrate 190, the insulating film 124, the insulating film 125, and the photoelectric conversion film 107. The support substrate 190 includes an array 104a of the pixel electrodes 104. The insulating film 124, the insulating film 125, and the photoelectric conversion film 107 are positioned above the support substrate 190. The support substrate 190 supports the photoelectric conversion film 107.

The support substrate 190 is provided with the recess 161. As is clear from FIGS. 3, 4A, and 4E, a continuous surface 171 including a defining surface 161s that defines the recess 161, a side surface 124s of the insulating film 124, and a side surface 125s of the insulating film 125 arranged in that order is provided at a position separate from the photoelectric conversion film 107 in plan view. The recess 161 may prevent a movement of moisture along an upper surface 191 of the support substrate 190. Therefore, this structure is suitable for providing a highly reliable imaging device 1.

The imaging device 1 includes at least one film. The film includes a portion positioned in the recess 161 and a portion positioned outside the recess 161 and above the support substrate 190. The film including the portion positioned in recess 161 may increase the adhesion strength between the support substrate 190 and the film. When the adhesion is increased, the entrance of moisture from the outside can be suppressed, and a highly reliable imaging device 1 may be provided. Specifically, the film is in contact with the recess 161. The portion positioned outside the recess 161 may be a portion that is positioned above the photoelectric conversion film 107 and that overlaps the photoelectric conversion film 107 in plan view. In the example illustrated in FIGS. 4B, 4C, and 4E, the at least one film includes at least one selected from the group consisting of the light-shielding film 121 and the insulating film 110.

The imaging device 1 includes a first film, a second film, and a third film. As illustrated in FIGS. 4A to 4E, the recess 161 includes a recess 162. As illustrated in FIGS. 4B and 4C, the first film includes an inner portion 121p positioned in the recess 161. The third film includes a second inner portion 126p positioned in the recess 161. A continuous surface 172 includes a defining surface 162s that defines the recess 162 and a side surface 121ps of the inner portion 121p. A continuous surface 173 includes a defining surface 163s that defines the recess 162 and a side surface 126ps of the second inner portion 126p. The second film is in contact with the continuous surface 172 and the continuous surface 173. In the illustrated example, the first film is the light-shielding film 121. The second film is the insulating film 110. The third film is the light-shielding film 126.

As illustrated in FIGS. 4D and 4E, in plan view, the recess 161 has a width W1 of, for example, greater than or equal to 100 nm. The width W1 is, for example, less than or equal to 10000 nm. In plan view, the recess 162 has a width W2 that is less than the width W1. The width W2 is, for example, greater than or equal to 50 nm. The width W2 is, for example, less than or equal to 10000 nm. In the example illustrated in FIGS. 4D and 4E, the width W1 is a dimension of the recess 161 in a short-side direction in plan view. The width W2 is a dimension of the recess 162 in a short-side direction in plan view.

As illustrated in FIG. 4D, the recess 161 has a depth D1 of, for example, greater than or equal to 10 nm and less than or equal to 600 nm. The depth D1 may be greater than or equal to 20 nm and less than or equal to 500 nm. The recess 162 has a depth D2 that is less than the depth D1. The depth D2 is, for example, greater than or equal to 5 nm and less than or equal to 400 nm. The depth D2 may be greater than or equal to 10 nm and less than or equal to 300 nm.

A difference D3 obtained by subtracting the depth D2 from the depth D1 is, for example, greater than or equal to 5 nm and less than or equal to 200 nm. The difference D3 may be greater than or equal to 10 nm and less than or equal to 200 nm. In one example, the depth D2 is greater than the difference D3. However, the depth D2 may be equal to the difference D3 or less than the difference D3.

As illustrated in FIG. 4E, in plan view, a length Lc of the recess 161 in a direction along the continuous surface 171 is longer than a length La of the array 104a of the pixel electrodes 104 in the direction along the continuous surface 171. In the example illustrated in FIG. 4E, when the number of pixel electrodes 104 included in the imaging device 1 is N (N is a natural number), the length La is a length of the smallest rectangle enclosing the array 104a of the N pixel electrodes 104 in plan view in the direction along the continuous surface 171. In the example illustrated in FIG. 4E, the direction along the continuous surface 171 is a long-side direction of the recess 161 in plan view. In the example illustrated in FIG. 4E, the array 104a has a matrix pattern. One of a row direction and a column direction of the pixel electrodes 104, specifically the column direction, is parallel to the long-side direction of the recess 161 in plan view. In addition, in plan view, the length Lc is longer than a length Li of the insulating film 125 in the direction along the continuous surface 171.

The recess 161 defines a step 180 on the support substrate 190. The step 180 may prevent a movement of moisture along the upper surface 191 of the support substrate 190. Therefore, this structure is suitable for providing a highly reliable imaging device 1.

### 3. Imaging Mechanism of Imaging Device 1

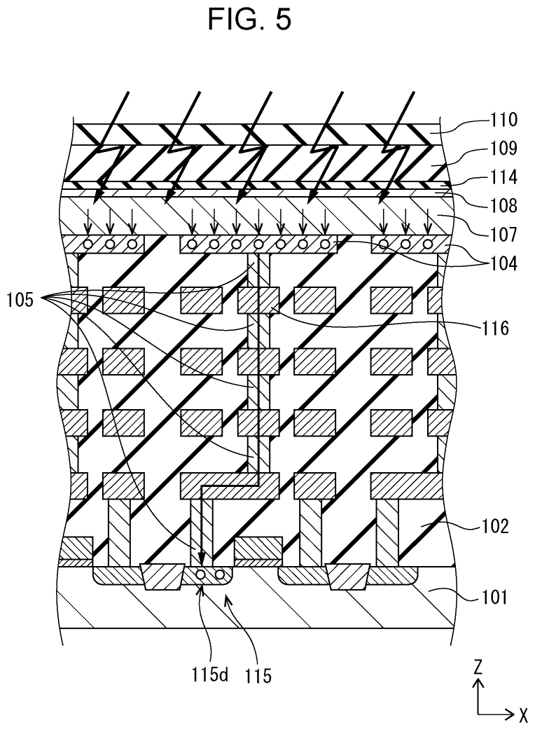

FIG. 5 illustrates an imaging mechanism. A voltage is applied from the counter-electrode voltage supplier 18 to the counter electrode 108 through the connection plug 106 and the connection electrode 103 in that order. Thus, a bias voltage is applied between each pixel electrode 104 and the counter electrode 108, and an electric field is applied to the photoelectric conversion film 107. In this state, light incident from above passes through the microlenses, the color filter, the insulating film 110, the insulating film 109, the insulating film 114, and the counter electrode 108 and is incident on the photoelectric conversion film 107. Accordingly, the photoelectric conversion film 107 performs photoelectric conversion on the incident light to generate electric charges. The electric charges generated by the photoelectric conversion film 107 are collected by the pixel electrodes 104, transmitted from the pixel electrodes 104 to the diffusing regions 115d through the pixel plugs 105, and are temporarily accumulated in the diffusing regions 115d. The accumulated electric charges are output as signals at appropriate timing in response to an opening/closing operation of, for example, transistor elements of the reading circuits 115.

### 4. Example of Method for Manufacturing Imaging Device 1

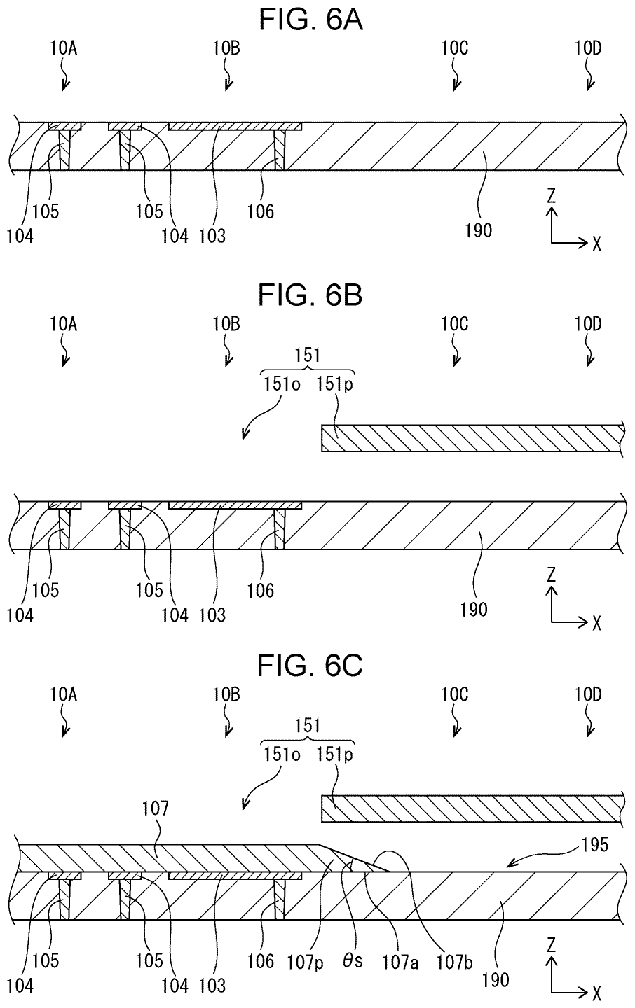

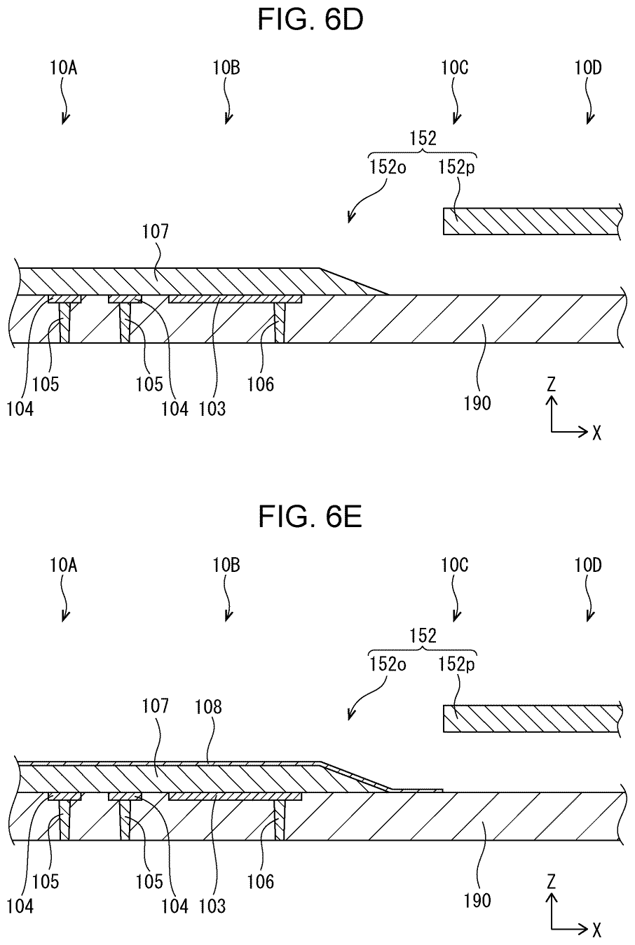

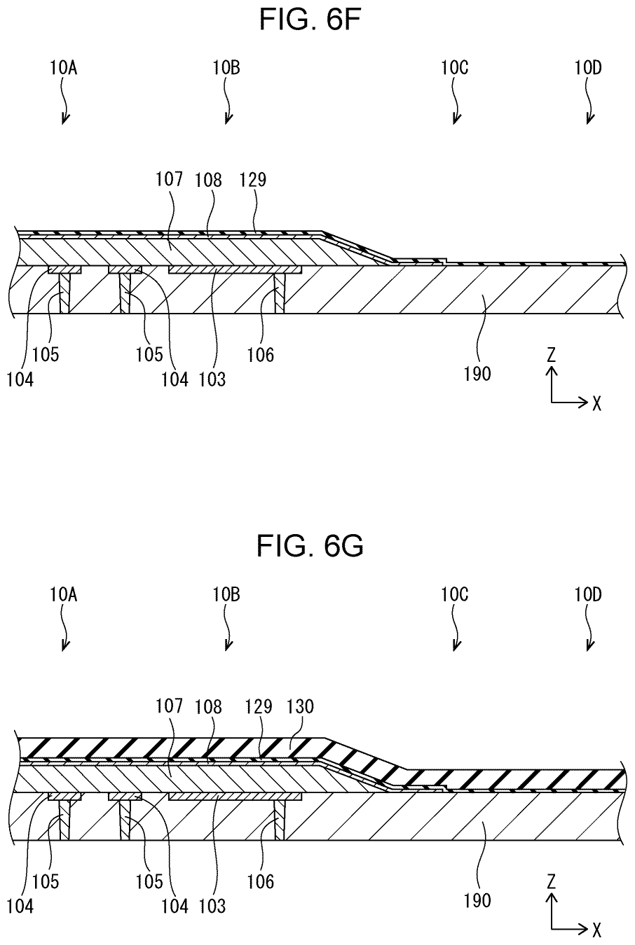

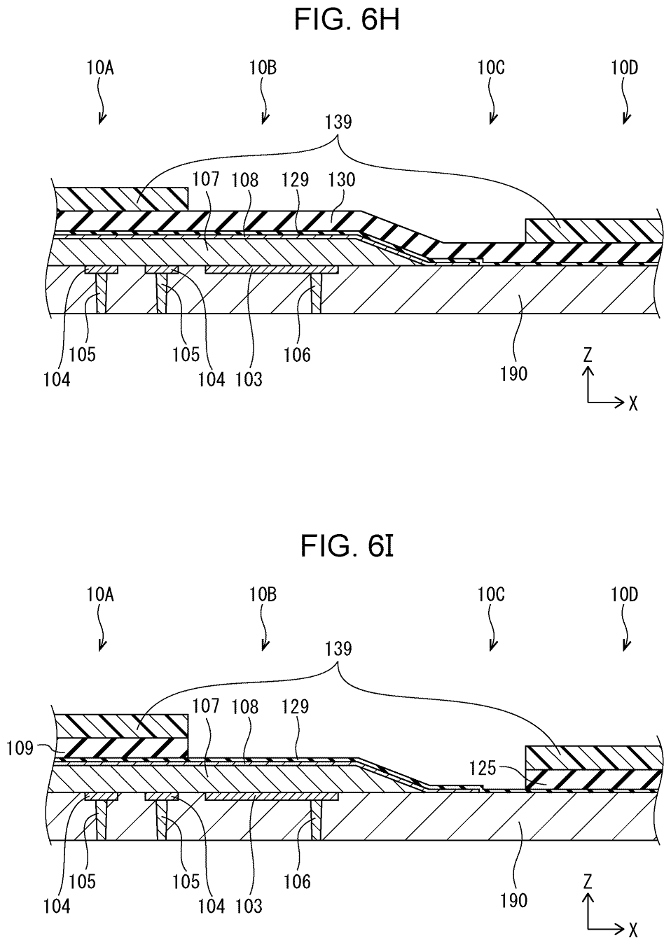

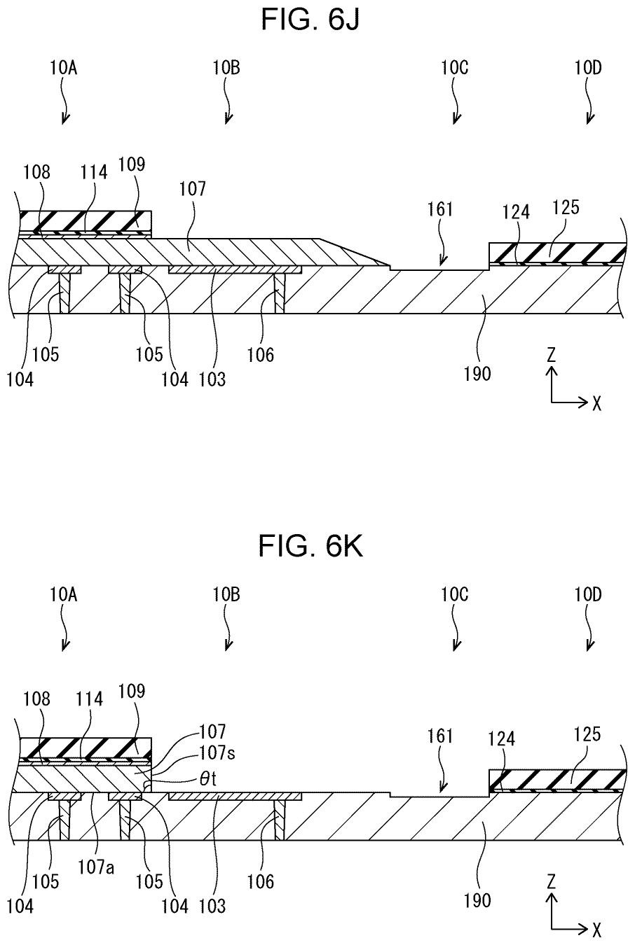

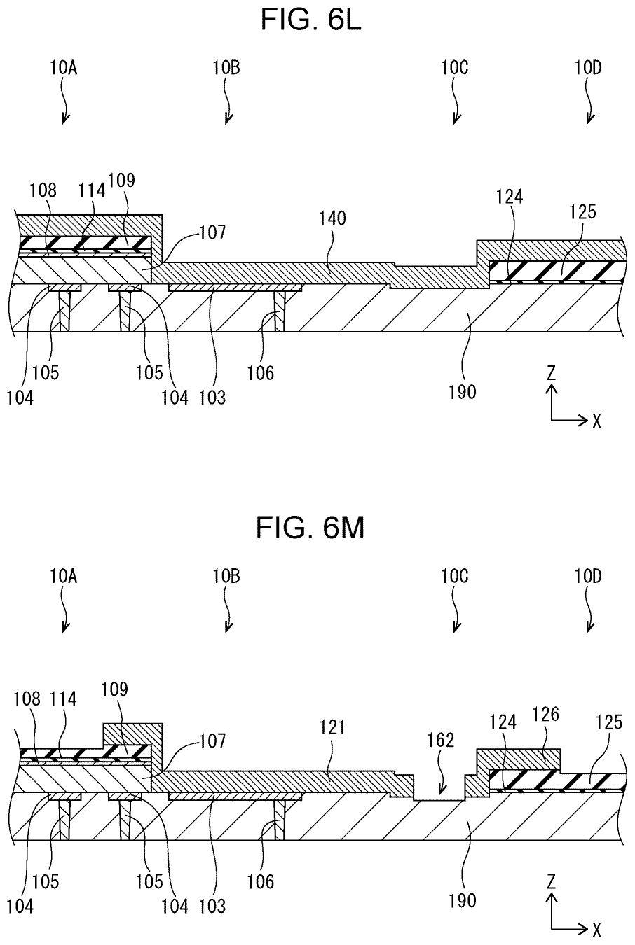

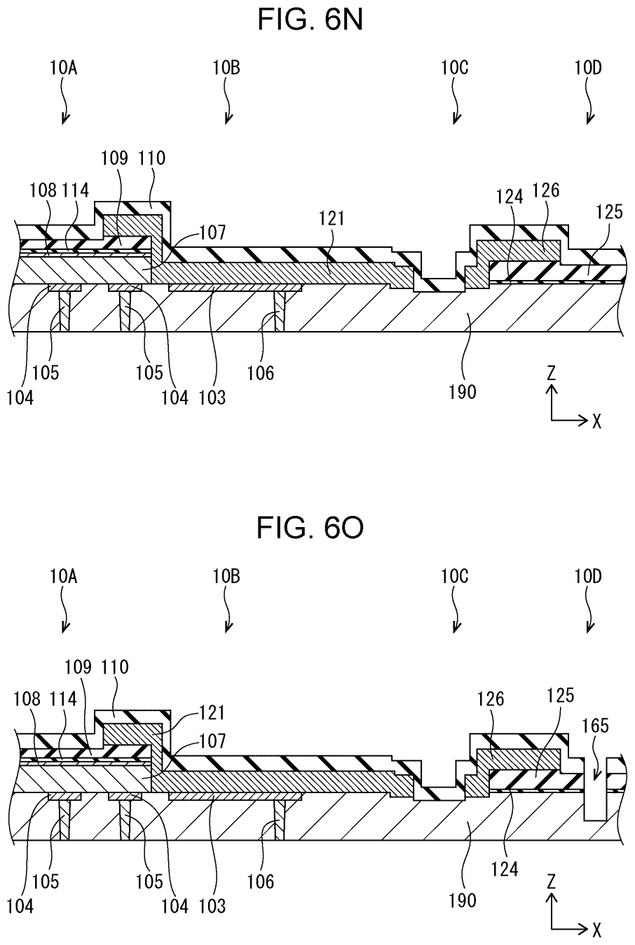

FIGS. 6A to 6O illustrate steps of a manufacturing method according to the first embodiment. Each of the steps performed after the structure illustrated in FIG. 6A is prepared will be described. This structure includes the support substrate 190.

A shadow mask 151 is placed above the structure illustrated in FIG. 6A. FIG. 6B schematically illustrates the shadow mask 151. The shadow mask 151 is a plate 151p having an opening 151o. The plate 151p is, for example, a metal plate.

Next, the material of the photoelectric conversion film 107 is deposited on the support substrate 190 from above through the opening 151o by vacuum deposition. Thus, the structure illustrated in FIG. 6C in which the pixel electrodes 104 and the connection electrode 103 are covered from above by the photoelectric conversion film 107 is obtained. In the present embodiment, the material of the photoelectric conversion film 107 includes an organic material. Specifically, the material includes an organic material as the main component. The thickness of the photoelectric conversion film 107 is, for example, 500 nm at locations directly above the pixel electrodes 104.

In plan view, the area of the opening 151o is less than the area of the support substrate 190. The photoelectric conversion film 107 is formed on the support substrate 190 in a limited region so that the photoelectric conversion film 107 does not overlap a predetermined region 195 of the support substrate 190 in plan view. In the example illustrated in FIG. 6C, the photoelectric conversion film 107 is formed in the pixel region 10A and the counter electrode region 10B. The predetermined region 195 belongs to the peripheral circuit region 10C. The predetermined region 195 may overlap the peripheral circuit in plan view.

In the example illustrated in FIG. 6C, the material of the photoelectric conversion film 107 flows downward through the opening 151o, and then flows into the region that overlaps the plate 151p. The photoelectric conversion film 107 is formed to include a slope portion 107p having a thickness that continuously decreases toward the outside. An angle θs between a lower surface 107a and a slope surface 107b of the slope portion 107p is, for example, greater than 0° and less than 45°, and may be greater than 0° and less than 30°.

After the photoelectric conversion film 107 is formed, the shadow mask 151 is removed. After that, a shadow mask 152 is placed above the structure. FIG. 6D schematically illustrates the shadow mask 152. The shadow mask 152 is a plate 152p having an opening 152o. The plate 152p is, for example, a metal plate. In the present embodiment, in plan view, the area of the opening 152o is greater than the area of the opening 151o.

Next, the material of the counter electrode 108 is deposited on the support substrate 190 from above through the opening 152o by physical vapor deposition (PVD). Thus, the structure illustrated in FIG. 6E in which the photoelectric conversion film 107 is covered from above by the counter electrode 108 is obtained. In the present embodiment, the material of the counter electrode 108 includes ITO. Specifically, the material includes ITO as the main component. After the counter electrode 108 is formed, the shadow mask 152 is removed.

Next, the material of an insulating film 129 is deposited on the support substrate 190 from above by chemical vapor deposition (CVD). Thus, the structure illustrated in FIG. 6F in which the counter electrode 108 is covered from above by the insulating film 129 is obtained. In the present embodiment, the material of the insulating film 129 includes aluminum oxide (AlO). Specifically, the material includes aluminum oxide as the main component. The thickness of the insulating film 129 is, for example, 30 nm.

As will become clear from the description below, the insulating film 114 is a portion of the insulating film 129. The insulating film 114 has better performance in protecting the photoelectric conversion film 107 than the counter electrode 108. Specifically, the insulating film 129 is formed by atomic layer deposition (ALD). The atomic layer deposition can be carried out without plasma, and therefore damage to the photoelectric conversion film 107 during formation of the insulating film 129 can be suppressed. The atomic layer deposition provides a high passivation effect, and therefore the insulating film 114 has a high protective function. In addition, the atomic layer deposition provides high coverage characteristics. Therefore, even when foreign matter is present on the photoelectric conversion film 107, regions in which the photoelectric conversion film 107 is not covered by the insulating film 114 are not easily formed.

After the insulating film 129 is formed, the material of an insulating film 130 is deposited above the structure by CVD. Thus, the structure illustrated in FIG. 6G in which the counter electrode 108 and the insulating film 129 are covered from above by the insulating film 130 is obtained. In the present embodiment, the material of the insulating film 130 includes silicon oxynitride (SiON). Specifically, the material includes silicon oxynitride as the main component. The thickness of the insulating film 130 is, for example, 200 nm.

Next, a resist pattern 139 is formed above the insulating film 130 by lithography. The resist pattern 139 is a pattern having an opening. Specifically, in plan view, the resist pattern 139 is disposed such that the resist pattern 139 overlaps the pixel electrodes 104 and that the opening overlaps the connection electrode 103. FIG. 6H schematically illustrates the resist pattern 139.

Next, the insulating film 130 is dry etched by using the resist pattern 139 as a mask. Thus, as illustrated in FIG. 6I, the insulating film 130 is divided into the insulating film 125 and the insulating film 109. After the dry etching process, the resist pattern 139 is removed by ashing.

Next, the counter electrode 108 and the insulating film 129 are dry etched by using the insulating film 109 and the insulating film 125 as a mask. The dry etching process has selectivity with respect to the counter electrode 108 and the insulating film 129 but has substantially no selectivity with respect to the insulating film 109, the insulating film 125, and the photoelectric conversion film 107. As a result of the dry etching process, portions of the counter electrode 108 and the insulating film 129 that do not overlap the insulating film 109 or the insulating film 125 in plan view are removed. Thus, as illustrated in FIG. 6J, the area of the counter electrode 108 in plan view is reduced, and the insulating film 129 is divided into the insulating film 114 and the insulating film 124. In addition, the recess 161 is formed in the support substrate 190 by over-etching in a region that does not overlap the insulating film 109, the insulating film 125, or the photoelectric conversion film 107 in plan view.

Next, the photoelectric conversion film 107 is dry etched by using the insulating film 109 as a mask. The dry etching process has a selectivity with respect to the photoelectric conversion film 107 but has substantially no selectivity with respect to the insulating film 109. As a result of the dry etching process, a portion of the photoelectric conversion film 107 that does not overlap insulating film 109 in plan view is removed. Thus, as illustrated in FIG. 6K, the area of the photoelectric conversion film 107 in plan view is reduced. The etching gas used in the dry etching process includes oxygen (O₂). The dry etching process progresses as the organic material of the photoelectric conversion film 107 and oxygen in the etching gas react to generate carbon oxide. As a result of the dry etching process, the side surface 107s of the photoelectric conversion film 107 is formed. An angle θt between the lower surface 107a and the side surface 107s is, for example, greater than or equal to 70° and less than or equal to 90°, and may be greater than or equal to 80° and less than or equal to 90°.

Next, the material of a light-shielding film 140 is deposited above the structure illustrated in FIG. 6K by CVD or PVD. Thus, the structure illustrated in FIG. 6L in which the insulating film 109, the connection electrode 103, the recess 161, and the insulating film 125 are covered from above by the light-shielding film 140 is obtained. In the present embodiment, the material of the light-shielding film 140 includes titanium (Ti) and titanium nitride (TiN). Specifically, the light-shielding film 140 includes a titanium layer and a titanium nitride layer stacked in that order in the upward direction. The thickness of the light-shielding film 140 is, for example, 400 nm.

Next, a resist pattern (not illustrated) is formed above the insulating film 140 by lithography. The light-shielding film 140 is dry etched by using the resist pattern as a mask. The dry etching process is performed so that a portion of the light-shielding film 140 that overlaps a portion of the recess 161 in plan view is removed. Thus, as illustrated in FIG. 6M, the light-shielding film 140 is divided into the light-shielding films 121 and 126. The recess 162 is formed in the support substrate 190 by over-etching in a region that overlaps a portion of the recess 161 in FIG. 6L in plan view. After the dry etching process, the resist pattern is removed by ashing.

Next, the material of the insulating film 110 is deposited above the structure illustrated in FIG. 6M by CVD. Thus, the structure illustrated in FIG. 6N is obtained. In the present embodiment, the material of the insulating film 110 includes silicon oxynitride (SiON). Specifically, the material includes silicon oxynitride as the main component. The thickness of the insulating film 110 is, for example, 400 nm.

Next, the recess 165 is formed in the pad region 10D by dry etching. FIG. 6O illustrates a structure in which the recess 165 is formed in the pad region 10D. After that, the pads 19 are placed on the bottom surface of the recess 165. Thus, the imaging device 1 illustrated in FIG. 3 is obtained.

In the above-described example, the photoelectric conversion film 107 is formed in a limited region within the region that overlaps the support substrate 190 in plan view by using the shadow mask 151. However, the photoelectric conversion film 107 may be formed in the above-described limited region by other methods, such as an inkjet method, a stamp method, or a lift-off method. The material of the photoelectric conversion film 107 may be a metal oxide, such as copper oxide.

In the above-described example, the counter electrode 108 is formed in a limited region within the region that overlaps the support substrate 190 in plan view by using the shadow mask 152. However, the counter electrode 108 may be formed in the above-described limited region by other methods, such as an inkjet method, a stamp method, or a lift-off method. The counter electrode 108 may be formed over the entire region that overlaps the support substrate 190 in plan view.

In the above-described example, the counter electrode 108, the photoelectric conversion film 107, and other elements are dry etched. When the photoelectric conversion film 107 is dry etched, the angle θt between the lower surface 107a and the side surface 107s of the photoelectric conversion film 107 can be increased. This is advantageous in that the area of the imaging device 1 can be reduced. However, other methods, such as wet etching or reverse sputtering, may be used instead of dry etching.

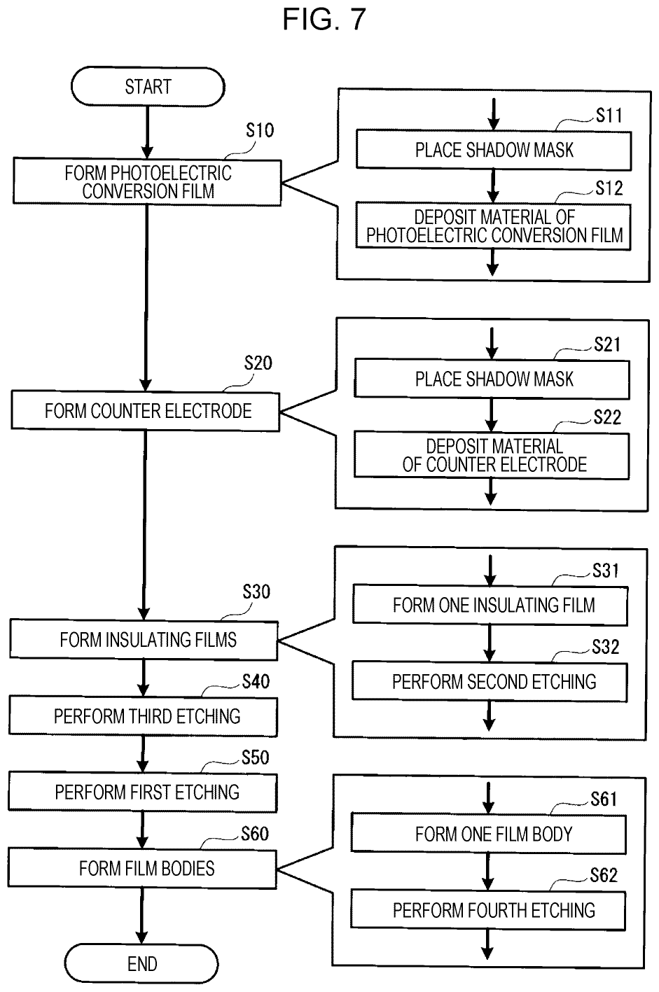

As is clear from the above description, the method for manufacturing the imaging device 1 according to the first embodiment may be described as below with reference to FIG. 7. FIG. 7 is a flowchart of the manufacturing method according to the first embodiment. The manufacturing method includes step S10 to step S60 in that order.

The manufacturing method uses the support substrate 190. The support substrate 190 includes the semiconductor substrate 101, the diffusing regions 115d, the pixel electrodes 104, and the connection electrode 103. The diffusing regions 115d are provided in the semiconductor substrate 101. The pixel electrodes 104 are electrically connected to the diffusing regions 115d. The connection electrode 103 is electrically separated from the pixel electrodes 104 and from the semiconductor substrate 101. In the completed imaging device 1, while a potential difference is applied between each pixel electrode 104 and the connection electrode 103, the photoelectric conversion film 107 performs photoelectric conversion to generate electric charges, which are collected by the pixel electrodes 104.

In step S10, the photoelectric conversion film 107 is formed above the support substrate 190 such that the photoelectric conversion film 107 does not overlap the predetermined region 195 of the support substrate 190 in plan view. In step S10, the photoelectric conversion film 107 is formed such that a first formation ratio is greater than 0% and less than 100%. The first formation ratio is a ratio of an overlapping area of the photoelectric conversion film 107 and the support substrate 190 in plan view to an area of the support substrate 190 in plan view. The first formation ratio may be greater than or equal to 10% and less than or equal to 90%, greater than or equal to 20% and less than or equal to 80%, or greater than or equal to 30% and less than or equal to 70%.

In step S10, the photoelectric conversion film 107 is formed by a film formation process that does not involve etching. In this context, the term “film formation” means the formation of a film in a region where no film is present.

In step S10, the photoelectric conversion film 107 is formed by using the shadow mask 151. When the shadow mask 151 is used, the overlapping area of the photoelectric conversion film 107 and the support substrate 190 in plan view can be easily controlled. Specifically, the overlapping area can be minimized, so that the amount of reduction in the area of the photoelectric conversion film 107 due to etching can be reduced.

Specifically, step S10 includes step S11 and step S12 in that order. The shadow mask 151 is the plate 151p having the opening 151o. In step S11, the shadow mask 151 is disposed such that the support substrate 190 includes a portion that overlaps the opening 151o and a portion that overlaps the plate 151p in plan view. In step S12, the material of the photoelectric conversion film 107 is deposited through the opening 151o. Therefore, the material may be prevented from being deposited on at least a part of the portion of the support substrate 190 that overlaps the plate 151p in plan view.

In step S20, the counter electrode 108 is formed such that the counter electrode 108 is positioned above the photoelectric conversion film 107 and that the counter electrode 108 overlaps the photoelectric conversion film 107 in plan view. In step S20, the counter electrode 108 is formed such that a second formation ratio is greater than 0% and less than 100%. The second formation ratio is a ratio of an overlapping area of the counter electrode 108 and the support substrate 190 in plan view to an area of the support substrate 190 in plan view. The second formation ratio may be greater than or equal to 10% and less than or equal to 90%, greater than or equal to 20% and less than or equal to 80%, or greater than or equal to 30% and less than or equal to 70%.

In step S20, the counter electrode 108 is formed by a film formation process that does not involve etching. In this context, the term “film formation” means the formation of a film in a region where no film is present.

In step S20, the counter electrode 108 is formed by using the shadow mask 152. When the shadow mask 152 is used, the overlapping area of the counter electrode 108 and the support substrate 190 in plan view can be easily controlled. Specifically, the overlapping area can be minimized, so that the amount of reduction in the area of the counter electrode 108 due to etching can be reduced.

Specifically, step S20 includes step S21 and step S22 in that order. The shadow mask 152 is the plate 152p having the opening 152o. In step S21, the shadow mask 152 is disposed such that the support substrate 190 includes a portion that overlaps the opening 152o and a portion that overlaps the plate 152p in plan view. In step S22, the material of the counter electrode 108 is deposited through the opening 152o. Therefore, the material may be prevented from being deposited on at least a part of the portion of the support substrate 190 that overlaps the plate 152p in plan view.

In step S30, the insulating film 125 and the insulating film 109 are formed. Specifically, step S30 includes step S31 and step S32 in that order.

In step S31, the insulating film 130 is formed to satisfy the following conditions:
the insulating film 130 includes a first insulator and a second insulator;
the first insulator is positioned above the predetermined region 195;
the first insulator overlaps the predetermined region 195 in plan view;
the second insulator is positioned above the photoelectric conversion film 107; and
the second insulator overlaps the photoelectric conversion film 107 in plan view.

In step S32, second etching is performed. As a result of the second etching, a portion of the insulating film 130 that is positioned between the first insulator and the second insulator is removed. Thus, the insulating film 125 corresponding to the first insulator and the insulating film 109 corresponding to the second insulator are formed. Specifically, the second etching is dry etching.

According to step S31 and step S32, in a region that overlaps the predetermined region 195 in plan view, the insulating film 125 that does not overlap the photoelectric conversion film 107 in plan view can be formed without a process of removing the photoelectric conversion film 107. In addition, the insulating film 109 that overlaps the photoelectric conversion film 107 in plan view can be formed. The insulating film 125 and the insulating film 109 can be formed at the same time by forming the insulating film 130 and performing the second etching.

In plan view, the insulating film 109 obtained in step S32 overlaps the pixel electrodes 104. Specifically, in plan view, the insulating film 109 overlaps the entireties of the pixel electrodes 104. In plan view, the above-described portion removed in step S32 overlaps the connection electrode 103. Specifically, in plan view, this portion overlaps the entirety of the connection electrode 103.

The imaging device 1 including the insulating film 125 and the insulating film 109 is manufactured. Therefore, the insulating function of the insulating film 125 and the insulating film 109 can be utilized in the imaging device 1.

In step S40, third etching is performed. As a result of the third etching, the area of the counter electrode 108 in plan view is reduced. Specifically, the third etching is dry etching.

As is clear from the above description, in step S20, the counter electrode 108 having a limited area is formed. In step S40, the area of this counter electrode 108 is reduced by the third etching. Thus, the amount of reduction in the area of the counter electrode 108 due to the third etching can be reduced, and the generation of etching residue can be suppressed. This may lead to an increase in the uniformity of the image quality.

The third etching is performed so that a portion of the counter electrode 108 that overlaps the pixel electrodes 104 in plan view remains. Specifically, the third etching is performed so that the entirety of the portion of the counter electrode 108 that overlaps the pixel electrodes 104 in plan view remains.

As a result of the third etching, a portion of the counter electrode 108 that overlaps the connection electrode 103 in plan view is removed. Thus, the imaging device 1 in which the connection electrode 103 and the counter electrode 108 do not overlap in plan view can be manufactured. Specifically, as a result of the third etching, the entirety of the portion of the counter electrode 108 that overlaps the connection electrode 103 in plan view is removed.

The third etching is performed after the structure described below is formed:
the photoelectric conversion film 107 is positioned above the support substrate 190;
the photoelectric conversion film 107 is positioned above the connection electrode 103;
the photoelectric conversion film 107 overlaps the connection electrode 103 in plan view;
the counter electrode 108 is positioned above the photoelectric conversion film 107;
the counter electrode 108 overlaps the photoelectric conversion film 107 in plan view;
the insulating film 125 is positioned above the support substrate 190;
the insulating film 125 is separate from both the photoelectric conversion film 107 and from the counter electrode 108 in plan view;
the insulating film 109 is positioned above the counter electrode 108; and
the insulating film 109 overlaps the counter electrode 108 in plan view.

The third etching includes etching in which the insulating film 109 is used as a mask and in which the area of the counter electrode 108 in plan view is reduced. The third etching also includes etching in which the insulating film 125 and the photoelectric conversion film 107 are used as a mask and in which the recess 161 is formed in the support substrate 190. Specifically, the recess 161 may be formed in the insulating layer 102f of the support substrate 190.

The selectivity of the third etching with respect to the counter electrode 108 is higher than the selectivity of the third etching with respect to the photoelectric conversion film 107. As a result of the third etching, the portion of the counter electrode 108 that overlaps the connection electrode 103 in plan view is removed. Specifically, as a result of the third etching, the entirety of the portion of the counter electrode 108 that overlaps the connection electrode 103 in plan view is removed.

The ratio of the area of the counter electrode 108 reduced by the third etching in plan view to the area of the support substrate 190 in plan view is defined as a second reduction ratio. The second reduction ratio is, for example, greater than 0% and less than or equal to 20%, and may be greater than 0% and less than or equal to 10%.

In step S50, first etching is performed. As a result of the first etching, the area of the photoelectric conversion film 107 in plan view is reduced. Specifically, the first etching is dry etching.

As is clear from the above description, in step S10, the photoelectric conversion film 107 having a limited area is formed. In step S50, the area of this photoelectric conversion film 107 is reduced by the first etching. Thus, the amount of reduction in the area of the photoelectric conversion film 107 due to the first etching can be reduced, and the generation of etching residue can be suppressed. This may lead to an increase in the uniformity of the image quality.

The first etching is performed so that a portion of the photoelectric conversion film 107 that overlaps the pixel electrodes 104 in plan view remains. Specifically, the first etching is performed so that the entirety of the portion of the photoelectric conversion film 107 that overlaps the pixel electrodes 104 in plan view remains.

As a result of the first etching, a portion of the photoelectric conversion film 107 that overlaps the connection electrode 103 in plan view is removed. Thus, the imaging device 1 in which the connection electrode 103 and the photoelectric conversion film 107 do not overlap in plan view can be manufactured. Specifically, as a result of the first etching, the entirety of the portion of the photoelectric conversion film 107 that overlaps the connection electrode 103 in plan view is removed.

As is clear from the above description, the third etching, in which the selectivity with respect to the photoelectric conversion film 107 is relatively low, is performed while the photoelectric conversion film 107 is positioned above the connection electrode 103 and while the photoelectric conversion film 107 and the connection electrode 103 overlap in plan view. After that, the first etching is performed to remove the portion of the photoelectric conversion film 107 that overlaps the connection electrode 103 in plan view. Thus, the connection electrode 103 can be protected from the third etching by the photoelectric conversion film 107. Specifically, the connection electrode 103 can be prevented from being reduced and having an increased electrical resistance. After the removal, an electrical path that electrically connects the connection electrode 103 to the counter electrode 108 is formed above the support substrate 190. As is clear from the description of step S60 below, the electrical path is a second film body, and may correspond to the light-shielding film 121.

In step S50, an insulating film mask is used in the first etching. The insulating film mask is not easily etched. Therefore, when the first etching is performed by using the insulating film mask, the generation of etching residue can be suppressed. This may lead to an increase in the uniformity of the image quality. Specifically, the insulating film mask may provide a high etching selectivity ratio for the photoelectric conversion film 107, and is therefore not easily etched. In addition, a typical insulating film mask does not include carbon that generates etching residue. This may also contribute to the suppression of the generation of etching residue. The insulating film mask may be the insulating film 109.

The ratio of the area of the photoelectric conversion film 107 reduced by the first etching in plan view to the area of the support substrate 190 in plan view is defined as a first reduction ratio. The first reduction ratio is, for example, greater than 0% and less than or equal to 20%, and may be greater than 0% and less than or equal to 10%.

The predetermined region 195 belongs to the peripheral circuit region 10C. The photoelectric conversion film 107 after the first etching belongs to the pixel region 10A.

In step S60, a first film body and a second film body are formed. Specifically, step S60 includes step S61 and step S62 in that order.

In step S61, a specific film body is formed to satisfy the following conditions:
the specific film body includes a first film portion and a second film portion;
the first film portion is positioned above the predetermined region 195;
the first film portion overlaps the predetermined region 195 in plan view;
the second film portion is positioned above the photoelectric conversion film 107; and
the second film portion overlaps the photoelectric conversion film 107 in plan view.

In step S62, fourth etching is performed. As a result of the fourth etching, an intermediate portion of the specific film body that is positioned between the first film portion and the second film portion is removed. Thus, the first film body corresponding to the first film portion and the second film body corresponding to the second film portion are formed.

According to step S61 and step S62, in a region that overlaps the predetermined region 195 in plan view, the first film body that does not overlap the photoelectric conversion film 107 in plan view can be formed without a process of removing the photoelectric conversion film 107. In addition, the second film body that overlaps the photoelectric conversion film 107 in plan view can be formed. The first film body and the second film body can be formed at the same time by forming the specific film body and performing the fourth etching. The specific film body, the first specific film, and the second specific film may correspond to the light-shielding film 140, the light-shielding film 126, and the light-shielding film 121, respectively.

In step S62, as a result of the fourth etching, the recess 162 is formed in a portion of the support substrate 190 that overlaps the intermediate portion in plan view.

### Second Embodiment

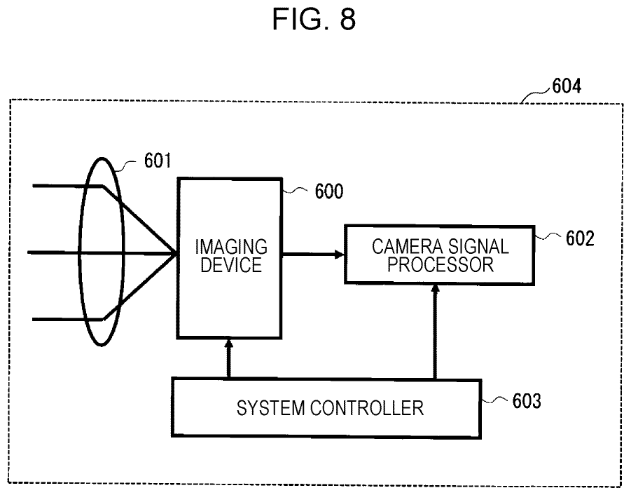

FIG. 8 is a schematic diagram of a camera system 604 according to a second embodiment. The camera system 604 includes an imaging device 600, an optical system 601, a camera signal processor 602, and a system controller 603. The above-described imaging device 1 of the first embodiment may be employed as the imaging device 600. The optical system 601 focuses light. The optical system 601 includes, for example, a lens. The camera signal processor 602 performs signal processing on the data of an image captured by the imaging device 600, and outputs the result as an image or data. The system controller 603 controls the imaging device 600 and the camera signal processor 602.

### Third Embodiment

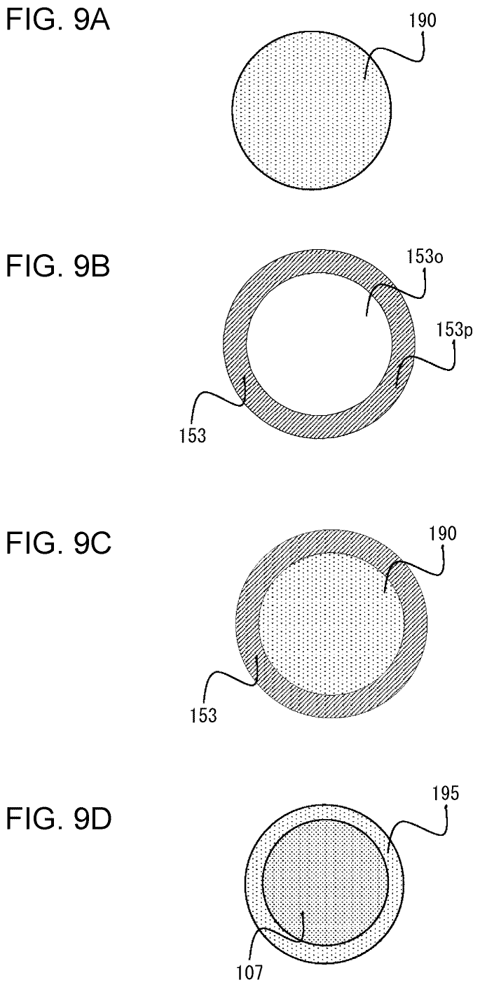

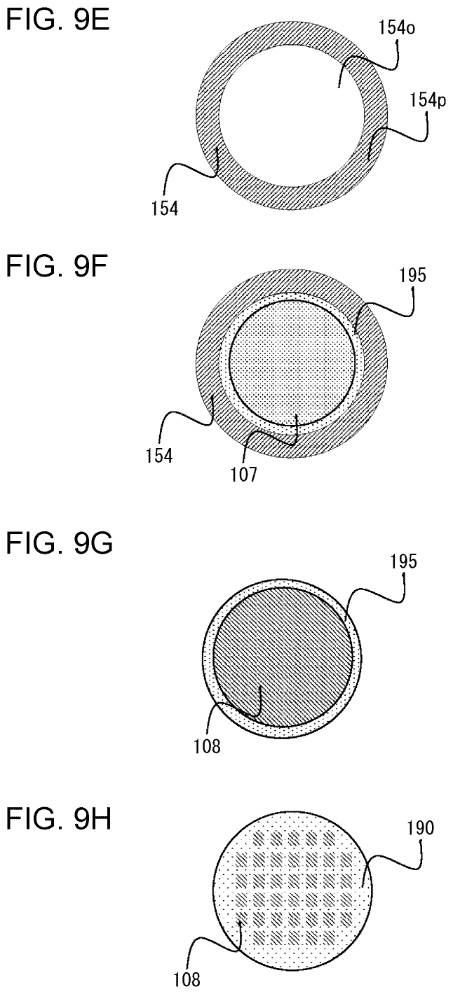

FIGS. 9A to 9F illustrate steps of a manufacturing method according to the third embodiment. Each of the steps performed after the structure illustrated in FIG. 9A is prepared will be described. This structure includes a support substrate 190.

A ring mask 153 is placed above the structure illustrated in FIG. 9A. FIG. 9B schematically illustrates the ring mask 153. The ring mask 153 is a plate 153p having an opening 153o. The plate 153p is, for example, a metal plate.

FIG. 9C schematically illustrates the structure in which the ring mask 153 is placed above the support substrate 190. The material of the photoelectric conversion film 107 is deposited on the support substrate 190 from above through the opening 153o by vacuum deposition. Thus, the structure illustrated in FIG. 9D in which the pixel electrodes 104 and the connection electrode 103 are covered from above by the photoelectric conversion film 107 is obtained. In the present embodiment, the material of the photoelectric conversion film 107 includes an organic material. Specifically, the material includes an organic material as the main component. The thickness of the photoelectric conversion film 107 is, for example, 500 nm at locations directly above the pixel electrodes 104.

In plan view, the area of the opening 153o is less than the area of the support substrate 190. The photoelectric conversion film 107 is formed on the support substrate 190 in a limited region so that the photoelectric conversion film 107 does not overlap a predetermined region 195 of the support substrate 190 in plan view. In the example illustrated in FIG. 9D, the photoelectric conversion film 107 is formed in the pixel region 10A and the counter electrode region 10B. In the example illustrated in FIG. 9D, the predetermined region 195 is an outer peripheral portion of the support substrate 190.

After the photoelectric conversion film 107 is formed, the ring mask 190 is removed. After that, a ring mask 154 is placed above the support substrate 190. FIG. 9E schematically illustrates the ring mask 154. The ring mask 154 is a plate 154p having an opening 154o. The plate 154p is, for example, a metal plate. In the present embodiment, in plan view, the area of the opening 154o is greater than the area of the opening 153o.

FIG. 9F schematically illustrates the structure in which the ring mask 154 is placed above the support substrate 190. The material of the counter electrode 108 is deposited on the support substrate 190 from above through the opening 152o by physical vapor deposition (PVD). Thus, the structure illustrated in FIG. 9G in which the photoelectric conversion film 107 is covered from above by the counter electrode 108 is obtained. In the present embodiment, the material of the counter electrode 108 includes ITO. Specifically, the material includes ITO as the main component. After the counter electrode 108 is formed, the ring mask 154 is removed.

The subsequent steps are similar to those in the first embodiment. The structure illustrated in FIG. 9H is obtained by dry etching the counter electrode 108, the photoelectric conversion film 107, and other elements. However, other methods, such as wet etching or reverse sputtering, may be used instead of dry etching.

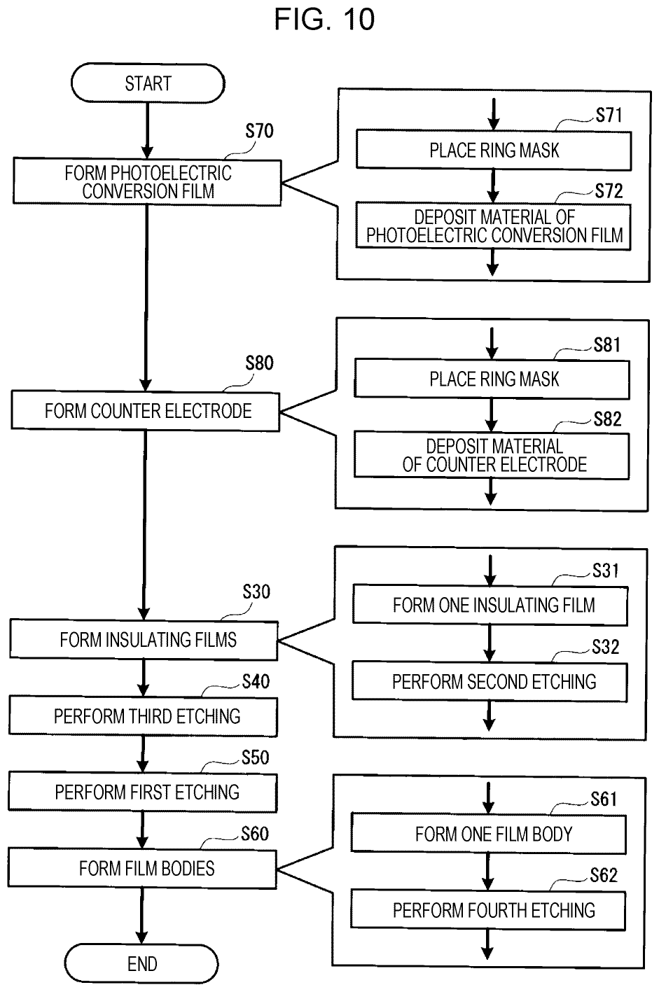

As is clear from the above description, the method for manufacturing the imaging device 1 according to the third embodiment may be described as below with reference to FIG. 10. FIG. 10 is a flowchart of the manufacturing method according to the third embodiment. The manufacturing method includes step S70 instead of step S10 in FIG. 7 and step S80 instead of step S20 in FIG. 7.

The method for manufacturing the imaging device 1 according to the third embodiment can be described similarly to the method for manufacturing the imaging device 1 according to the first embodiment except that the shadow masks are replaced by the ring masks. Therefore, description of steps S30 to S60 will be omitted.

In step S70, the photoelectric conversion film 107 is formed above the support substrate 190 such that the photoelectric conversion film 107 does not overlap the predetermined region 195 of the support substrate 190 in plan view. In step S70, the photoelectric conversion film 107 is formed such that a first formation ratio is greater than 0% and less than 100%. The first formation ratio is a ratio of an overlapping area of the photoelectric conversion film 107 and the support substrate 190 in plan view to an area of the support substrate 190 in plan view. The first formation ratio may be greater than or equal to 10% and less than or equal to 90%, greater than or equal to 20% and less than or equal to 80%, or greater than or equal to 30% and less than or equal to 70%.

In step S70, the photoelectric conversion film 107 is formed by a film formation process that does not involve etching. In this context, the term “film formation” means the formation of a film in a region where no film is present.

In step S70, the photoelectric conversion film 107 is formed by using the ring mask 153. When the ring mask 153 is used, the overlapping area of the photoelectric conversion film 107 and the support substrate 190 in plan view can be easily controlled. Specifically, the overlapping area can be minimized, so that the film formation stress applied to the substrate can be reduced. The ring mask has a larger clearance for the film formation region than the shadow mask, and it is not necessary to strictly define the film formation region. Therefore, a thick mask can be used. A thick mask requires less frequent maintenance, and accordingly the process costs can be reduced.

Specifically, step S70 includes step S71 and step S72 in that order. The ring mask 153 is the donut-shaped plate 153p having the opening 153o. In step S71, the ring mask 153 is disposed such that the support substrate 190 includes a portion that overlaps the opening 153o and a portion that overlaps the donut-shaped plate 153p in plan view. In step S72, the material of the photoelectric conversion film 107 is deposited through the opening 153o. Therefore, the material may be prevented from being deposited on at least a part of the portion of the support substrate 190 that overlaps the plate 153p in plan view. In particular, since the ring mask 153 is used, the film can be prevented from being formed in an outer peripheral portion of the support substrate 190 that is not unnecessary when the pixels are formed, and the film formation stress applied to the substrate can be reduced.

In step S80, the counter electrode 108 is formed such that the counter electrode 108 is positioned above the photoelectric conversion film 107 and that the counter electrode 108 overlaps the photoelectric conversion film 107 in plan view. In step S80, the counter electrode 108 is formed such that a second formation ratio is greater than 0% and less than 100%. The second formation ratio is a ratio of an overlapping area of the counter electrode 108 and the support substrate 190 in plan view to an area of the support substrate 190 in plan view. The second formation ratio may be greater than or equal to 10% and less than or equal to 90%, greater than or equal to 20% and less than or equal to 80%, or greater than or equal to 30% and less than or equal to 70%.

In step S80, the counter electrode 108 is formed by a film formation process that does not involve etching. In this context, the term “film formation” means the formation of a film in a region where no film is present.

In step S80, the counter electrode 108 is formed by using the ring mask 154. When the ring mask 154 is used, the overlapping area of the counter electrode 108 and the support substrate 190 in plan view can be easily controlled. Specifically, the overlapping area can be minimized, so that the film formation stress applied to the substrate can be reduced.

Specifically, step S80 includes step S81 and step S82 in that order. The ring mask 154 is the donut-shaped plate 154p having the opening 154o. In the present embodiment, in plan view, the area of the opening 154o is greater than the area of the opening 153o. In step S81, the ring mask 154 is disposed such that the photoelectric conversion film 107 and a portion of the support substrate 190 on which the photoelectric conversion film 107 is not formed include portions that overlap the opening 154o. In addition, the ring mask 154 is disposed such that the donut-shaped plate 154p includes a portion that overlaps the portion of the support substrate 190 on which the photoelectric conversion film 107 is not formed in plan view. In step S82, the material of the counter electrode 108 is deposited through the opening 154o. Therefore, the material may be prevented from being deposited on at least a part of the portion of the support substrate 190 that overlaps the plate 154p in plan view.

For steps S30 to S60, refer to the description of the first embodiment.

According to the present disclosure, an imaging device to be mounted in a digital still camera or the like can be provided.

What is claimed is:

1. A method for manufacturing an imaging device, the method comprising:
forming a specific insulating film including a second insulator such that the second insulator is positioned above a photoelectric conversion film and that the second insulator overlaps the photoelectric conversion film in plan view; and
performing second etching to remove a portion that is included in the specific insulating film and that is in contact with the second insulator, thereby forming a second insulating film corresponding to the second insulator.

2. The method according to claim 1, further comprising:
forming the photoelectric conversion film above a support substrate such that the photoelectric conversion film does not overlap a predetermined region of the support substrate in plan view;
forming the specific insulating film such that the specific insulating film includes a first insulator, that the first insulator is positioned above the predetermined region, and that the first insulator overlaps the predetermined region in plan view; and
forming a first insulating film corresponding to the first insulator,
wherein the portion that is included in the specific insulating film and that is in contact with the second insulator is in contact with the first insulator, and
wherein the first insulating film is formed when the portion that is included in the specific insulating film and that is in contact with the second insulator is removed.

3. The method according to claim 1, further comprising:
forming a counter electrode such that a ratio of an overlapping area of the counter electrode and a support substrate in plan view to an area of the support substrate in plan view is greater than 0% and less than 100%, that the counter electrode is positioned above the photoelectric conversion film, and that the counter electrode overlaps the photoelectric conversion film in plan view; and
performing third etching to reduce an area of the counter electrode in plan view.

4. The method according to claim 1, further comprising:
performing third etching after a structure is formed in which the photoelectric conversion film is positioned above a support substrate, in which a counter electrode is positioned above the photoelectric conversion film, in which the counter electrode overlaps the photoelectric conversion film in plan view, in which the second insulating film is positioned above the counter electrode, and in which the second insulating film overlaps the counter electrode in plan view,
wherein the third etching includes
etching in which the second insulating film serves as a mask and in which an area of the counter electrode in plan view is reduced, and
etching in which the photoelectric conversion film serves as a mask and in which a first recess is formed in the support substrate.

5. The method according to claim 1,
wherein a support substrate includes a connection electrode, and
wherein the method further comprises:
performing third etching after a structure is formed in which the photoelectric conversion film is positioned above the connection electrode, in which the photoelectric conversion film overlaps the connection electrode in plan view, in which a counter electrode is positioned above the photoelectric conversion film, and in which the counter electrode overlaps the photoelectric conversion film in plan view, the third etching having a higher selectivity with respect to the counter electrode than with respect to the photoelectric conversion film, thereby removing a portion of the counter electrode that overlaps the connection electrode in plan view; and
performing first etching after the third etching to reduce an area of the photoelectric conversion film in plan view, thereby removing a portion of the photoelectric conversion film that overlaps the connection electrode in plan view.

6. The method according to claim 1, further comprising:
forming a specific film body such that the specific film body includes a first film portion and a second film portion, that the first film portion is positioned above the predetermined region, that the first film portion overlaps the predetermined region in plan view, that the second film portion is positioned above the photoelectric conversion film, and that the second film portion overlaps the photoelectric conversion film in plan view; and
performing fourth etching to remove an intermediate portion of the specific film body that is positioned between the first film portion and the second film portion, thereby forming a first film body corresponding to the first film portion and a second film body corresponding to the second film portion.

7. The method according to claim 6,
wherein the fourth etching is performed to form a second recess in a portion of the support substrate that overlaps the intermediate portion in plan view.

8. The method according to claim 2,
wherein the predetermined region is included in a peripheral circuit region.

9. The method according to claim 6,
wherein the predetermined region is included in a peripheral circuit region.

10. An imaging device comprising:
a support substrate including a first portion recessed from a central portion;
a first insulating film positioned above the support substrate;
a photoelectric conversion film positioned above the support substrate; and
at least one film including a portion positioned in the first portion,
wherein the first portion is positioned outside the central portion,
wherein a first continuous surface is provided at a position separate from the photoelectric conversion film in plan view, the first continuous surface including a first defining surface that defines the first portion with respect to the central portion and a side surface of the first insulating film, and
wherein the at least one film is not conductive.

11. The imaging device according to claim 10,
wherein the at least one film includes at least one selected from the group consisting of a light-shielding film and a second insulating film.

12. The imaging device according to claim 10, further comprising:
a first film,
wherein the first portion includes a second portion,
wherein the first film includes an inner portion positioned in the first portion, and
wherein a second continuous surface is provided, the second continuous surface including a second defining surface that defines the second portion and a side surface of the inner portion.

13. The imaging device according to claim 12, further comprising:
a second film,
wherein the second film is in contact with the second continuous surface.

14. The imaging device according to claim 10,
wherein the support substrate includes an array of pixel electrodes, and
wherein, in plan view, a length of the first portion in a direction along the first continuous surface is longer than a length of the array in the direction along the first continuous surface.

15. The imaging device according to claim 10,
wherein the first portion defines a step on the support substrate.
